(19) United States
(12) Patent Application Publication
(10) Pub. No.: US 2026/0304709 A1
(43) Pub. Date: Oct. 1, 2026

(54) HARDWARE SECURITY MODULE APPLIANCE

(71) Applicant: ENTRUST SECURITY UK LIMITED, Cambridge (GB)

(72) Inventors: Daniel Patrick EVES, London (GB); Med TALLY, Southwick (GB); Giacomo ZANICHELLI, Cambridge (GB)

(21) Appl. No.: 19/541,095

(22) Filed: Feb. 16, 2026

Related U.S. Application Data
(60) Provisional application No. 63/781,690, filed on Apr. 1, 2025.

(51) Int. Cl. H05K 7/20

(52) U.S. Cl. CPC H05K 7/20727; H05K 7/20145; H05K 7/20172; H05K 7/20745; H05K 7/20754; H05K 7/20836

(57) ABSTRACT

A hardware security module (HSM) appliance that include one or more HSM(s) is described. The HSM appliance provides improved cooling of HSM appliance components including the HSM(s), improved maintenance, and improved security. In an embodiment, the HSM(s) and a processor module that controls operation of the HSM(s) are positioned relative to one another whereby the HSM(s) and the processor module overlap one another. In another embodiment, cooling air ducting may cover the HSM(s) and the processor module, with the cooling air ducting directing cooling air over the HSM(s) and the processor module.

### PRIORITY

This application claims the benefit of priority to provisional application Ser. No. 63/781690 filed on Apr. 1, 2025, the entire contents of which are incorporated herein by reference.

### FIELD

The technology described herein is directed to a hardware security module (HSM) appliance having an HSM having at least one cryptographic key stored thereon.

### BACKGROUND

HSMs are devices that securely store and manage cryptographic keys, and perform a set of cryptographic functions. HSMs may be used in a number of applications including, but not limited to, securing transactions and communications. HSMs can be general purpose HSMs used in applications such as crypto wallets, public key infrastructure (PKI), and in the security of basic sensitive data. HSMs may also be application specific, for example designed for use in payment and/or transaction applications designed to protect credit and payment card information, as well as other sensitive information involved in financial transactions, or designed for use in financial card personalization applications, such as programming integrated circuit chips on financial cards and other personalized cards, to protect cardholder information.

### SUMMARY

Improvements to an HSM appliance that include one or more HSM(s) are described. The HSM appliance is a device that includes the HSM(s) which is one component (i.e. a subcomponent) of the HSM appliance. The described HSM appliance provides improved cooling of HSM appliance components including the HSM(s), improved maintenance, and improved security.

For example, in one embodiment, the HSM and a processor module that controls operation of the HSM(s) are positioned relative to one another whereby the HSM(s) and the processor module overlap one another. This positions the HSM(s) and the processor module relative to one another within the HSM appliance to facilitate more efficient cooling of the HSM(s) and of the processor module.

In an embodiment, the side edge of the HSM(s) may overlap the side edge of the processor module. The side edge of the HSM(s) may be parallel to the side edge of the processor module.

In another embodiment, cooling air ducting may cover the HSM(s) and the processor module, with the cooling air ducting directing cooling air over the HSM(s) and the processor module. The ducting may have any configuration that covers the HSM(s) and the processor module to direct cooling air over the HSM(s) and the processor module. By directing the cooling air over the HSM(s) and the processor module, more efficient cooling of the HSM(s) and the processor module is achieved.

In one example, the ducting may be configured so that cooling air in the ducting is turned less than 90 degrees within the ducting as the cooling air flows to the HSM(s) and the processor module. The HSM appliance includes cooling fans that generate the flow of cooling air. Each cooling fan has an air discharge axis, and the discharge axis of at least one of the cooling fans extends through the HSM(s) so that air flows more directly to the HSM(s). These features of the ducting, individually and together, provides more efficient flow of the cooling air in the ducting, improving the performance of the cooling fans.

In an embodiment, the ducting may also include a branch that directs cooling air to a network interface module that includes a plurality of network ports. Or ducting that is separate from the HSM and processor module ducting may be provided to direct cooling air from the cooling fans (or a separate cooling fan(s)) to the network interface module.

The HSM appliance may also include baffles to prevent insertion of probes into the HSM appliance and/or prevent an inserted probe from reaching the HSM(s) or the processor module. For example, baffles may be included in the ducting, for example upstream and/or downstream of the HSM(s) and the processor module. Baffles may also or alternatively be included in cooling air outlets from the HSM appliance. Baffles may also or alternatively be included in the ducting branch that directs cooling air to the network interface module.

In another embodiment, the cooling fans may be individually hot swappable whereby the cooling fans can be replaced without stopping or shutting down the HSM appliance.

In another embodiment, the HSM appliance may include one or more battery modules that provides power to maintain some functions of the HSM appliance and the HSM when main power has been removed. The battery module(s) may be hot swappable whereby the battery module(s) can be replaced without stopping or shutting down the HSM appliance.

In another embodiment, the HSM appliance may include one or more power supply modules that may be hot swappable whereby the power supply module(s) can be replaced without stopping or shutting down the HSM appliance.

In an embodiment, the speed of the cooling fans may be dynamically controlled based on various temperature measurements. For example, one or more temperature sensors may be provided on the HSM(s) and/or on the processor module to sense the temperature of each HSM and/or sense the temperature of the processor module. The speed of the cooling fans may be dynamically controlled, for example the fan speed may be adjusted up or down, based on one or more of these temperature measurements. In addition to or separately from the temperature sensors on the HSM(s) and/or the processor module, one or more air temperature sensors may be provided before (i.e. air inlet air temperature sensors) and after (i.e. air outlet air temperature sensors) the HSM(s) and/or before (i.e. air inlet air temperature sensors) and after (i.e. air outlet air temperature sensors) the processor module. The air temperature sensors may be provided in each branch of the cooling air ducting. The air temperature sensors are configured to detect the temperature of the cooling air at the respective locations of the sensors from which, for example, an increase in temperature (if any) of the cooling air as a result of flowing past the HSM(s) and/or the processor module can be determined. The speed of the cooling fans may be dynamically controlled, for example the speed thereof adjusted up or down, depending upon the cooling needs of the HSM(s) and/or processor module as indicated by the temperature measurement(s) of the temperature sensors on the HSM(s) and/or on the processor module, and/or based on the temperature measurements of the air temperature sensors.

In one specific example, an HSM appliance can include a housing defining an interior space; an HSM disposed in the interior space, the HSM having at least one cryptographic key stored thereon; and a processor module disposed in the interior space, the processor module is in communication with the HSM and controls operation of the HSM and the HSM appliance. The HSM and the processor module are positioned relative to one another within the interior space whereby the HSM and the processor module overlap one another.

In another example, an HSM appliance can include a housing defining an interior space; an HSM disposed in the interior space, the hardware security module having at least one cryptographic key stored thereon; and a processor module disposed in the interior space, the processor module is in communication with the HSM and controls operation of the HSM. A cooling system is disposed within the interior space with the cooling system including cooling fans adjacent a first end wall of the housing that draw cooling air into the interior space, cooling air outlets in a second end wall of the housing opposite the first end wall through which cooling air drawn into the interior space exits the interior space, and cooling air ducting that extends from the cooling fans to the cooling air outlets. The cooling air ducting covers the HSM and the processor module and directs cooling air that is drawn into the interior space over the HSM and the processor module before the cooling air flows to the cooling air outlets.

In another example, an HSM appliance can include a housing defining an interior space; an HSM disposed in the interior space, the hardware security module having a plurality of cryptographic keys stored thereon; and a processor module disposed in the interior space, the processor module is in communication with the HSM and controls operation of the HSM. A cooling system is disposed within the interior space, with the cooling system including cooling fans adjacent a first end wall of the housing that draw cooling air into the interior space, cooling air outlets in a second end wall of the housing opposite the first end wall through which cooling air drawn into the interior space exits the interior space, and cooling air ducting that distributes cooling air from the cooling fans within the interior space. In addition, at least two of the following apply: a) the HSM and the processor module are positioned relative to one another within the interior space so that sides of the HSM and the processor module overlap one another; b) the cooling air ducting extends from the cooling fans to the cooling air outlets, and the cooling air ducting covers the HSM and the processor module and directs cooling air that is drawn into the interior space over the HSM and the processor module before the cooling air flows to the cooling air outlets; c) the cooling air ducting is configured whereby the cooling air flowing through the cooling air ducting is turned less than 90 degrees; and d) each cooling fan has a discharge axis, and the discharge axis of at least one of the cooling fans extends through the HSM. In an embodiment, at least three of a), b), c) and d) apply. In another embodiment, each of a), b), c) and d) apply.

In another example, an HSM appliance can include a housing defining an interior space; an HSM disposed in the interior space, the hardware security module having a plurality of cryptographic keys stored thereon; and a processor module disposed in the interior space, the processor module is in communication with the HSM and controls operation of the HSM. A cooling system is disposed within the interior space, with the cooling system including cooling fans adjacent a first end wall of the housing that draw cooling air into the interior space, cooling air outlets in a second end wall of the housing opposite the first end wall through which cooling air drawn into the interior space exits the interior space, and cooling air ducting that distributes cooling air from the cooling fans within the interior space. The cooling fans may be individually hot swappable whereby the cooling fans can be replaced without stopping or shutting down the HSM appliance.

In an embodiment, the HSM appliance may be a 1U appliance. However, other sizes of the HSM appliance are possible.

The HSM(s) in the HSM appliance can be a general purpose HSM or an application specific HSM designed for a specific application. The HSM(s) can be used in crypto wallets, public key infrastructure (PKI), the security of basic sensitive data, used in payment and/or transaction applications designed to protect credit and payment card information as well as other sensitive information involved in financial transactions, used in financial card personalization applications such as programming integrated circuit chips on financial cards and other personalized cards to protect cardholder information. Additional example uses of the HSM(s) and the HSM appliance described herein include, but are not limited to: key management; digital signing; code signing; blockchain; Internet-of-things (IOT); certificate management; identity and user authentication; payment security; encryption; database security; tokenization; privileged access and secrets management; cloud containers; active directory certificates services; firewalls; and transport layer security/secure socket layer inspection.

### DRAWINGS

FIG. 1 is a perspective view of the HSM appliance described herein.

FIG. 2 is an exploded perspective view of the HSM appliance.

FIG. 3A is a top view of the HSM appliance.

FIG. 3B is a top view of the HSM appliance with the top of the cooling air ducting removed and other components removed for clarity.

FIG. 4A is a top perspective view of a top portion of a front section of the cooling air ducting.

FIG. 4B is a bottom perspective view of the top portion of the front or upstream section of the cooling air ducting.

FIG. 4C is a top perspective view of a bottom portion of the front or upstream section of the cooling air ducting.

FIG. 5 is a bottom view of a rear or downstream section of the cooling air ducting.

FIG. 6 is a schematic depiction of an example application of the HSM appliance.

FIG. 7 depicts an example of a dynamic fan speed control system that controls the speed of one or more of the cooling fans.

### DETAILED DESCRIPTION

The following is a description of an HSM appliance that include one or more HSM(s). The HSM appliance is a device that includes the HSM(s) which is one component (i.e. a subcomponent) of the HSM appliance which includes other components. The HSM appliance and the HSM(s) therein can be configured for any application including, but not limited to, securing transactions and communications. The HSM appliance and the HSM(s) therein can be a general purpose HSM appliance or configured for a specific application. The HSM appliance and the HSM(s) therein can be used in crypto wallets, public key infrastructure (PKI), the security of basic sensitive data, used in payment and/or transaction applications designed to protect credit and payment card information as well as other sensitive information involved in financial transactions, used in financial card personalization applications such as programming integrated circuit chips on financial cards and other personalized cards to protect cardholder information. Additional example uses of the HSM appliance and the HSM(s) therein include, but are not limited to: key management; digital signing; code signing; blockchain; Internet-of-things (IOT); certificate management; identity and user authentication; payment security; encryption; database security; tokenization; privileged access and secrets management; cloud containers; active directory certificates services; firewalls; and transport layer security/secure socket layer inspection.

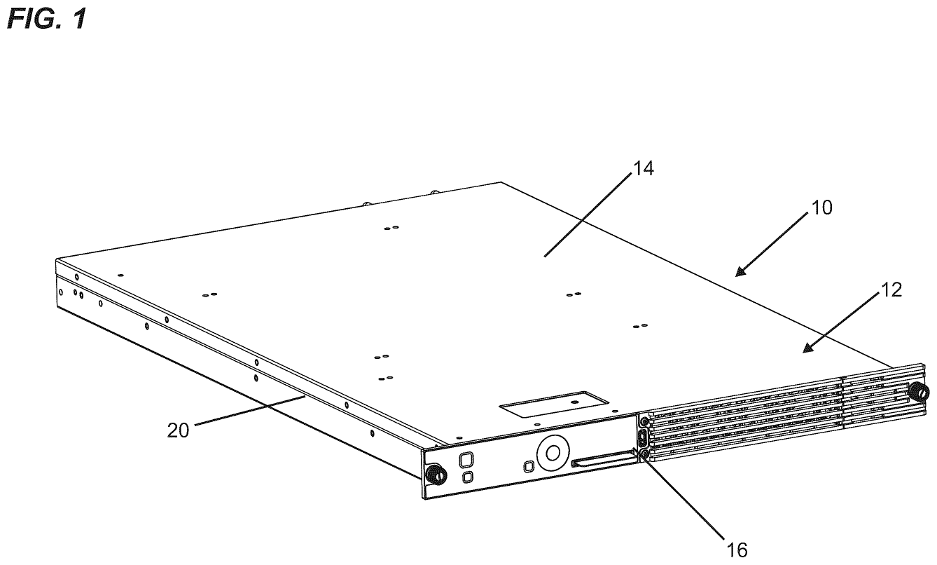

Referring to FIG. 1, an example of the HSM appliance 10 is illustrated. In this example, the HSM appliance 10 is configured as a module which may be removably installed within a rack similar to a rack-mounted appliance like a server. In other embodiments, the appliance 10 may have other configurations and need not be installed in a rack. When installed in a rack, the HSM appliance 10 may be one of a plurality of other similarly configured HSM appliances that are also installed on the rack. The appliance 10 may be oriented so that it is oriented in a vertical plane (for example, on one of its edge panels) or oriented in a horizontal plane (for example, in the orientation shown in FIG. 1) during use, whether installed in a rack or not installed in a rack.

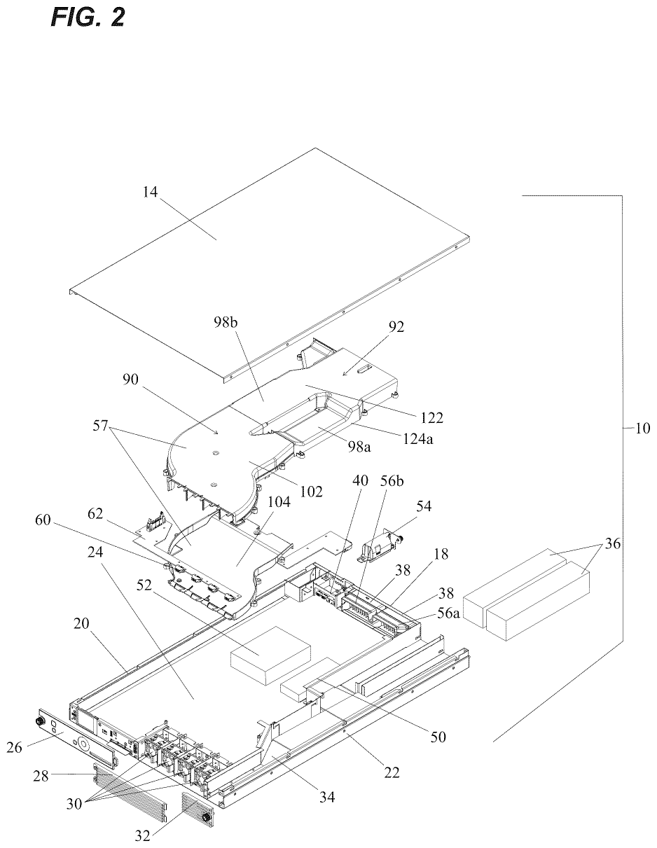

With continued reference to FIG. 1 together with FIG. 2, the appliance 10 includes a housing 12 (also referred to as an enclosure) that has a first panel 14 (which may be referred to as a top panel based on the orientation in FIG. 1 or as a side panel), a second panel (not visible in FIG. 1 and which may be referred to as a bottom panel based on the orientation in FIG. 1 or as a side panel) that is opposite and parallel to the first panel 14, a front panel 16, a rear panel 18 (visible in FIG. 2) that is opposite and parallel to the front panel 16, a first edge panel 20, and a second edge panel 22 (visible in FIG. 2) that is opposite and parallel to the first edge panel 20. The housing 12 defines an interior space 24 in which various components of the appliance 10 are disposed. One or more of the panels, such as the first panel 14, may be removable to allow access to the interior space 24 and to the components therein.

Referring to FIGS. 1 and 2, the front panel 16 can include a control panel section 26 that allows user inputs and provides one or more operational status indicators. The front panel 16 can also include a fan panel section 28 that covers cooling fans 30 and forms a cooling air inlet through which cooling air drawn in by the cooling fans 30 can enter the appliance 10. Further, the front panel 16 is depicted as including a power supply panel section 32 that covers the entrance to a channel 34 and through which cooling air can enter the channel 34 to be directed to one or more power supply modules 36. Air may be drawn into the channel 34 by fans mounted on the power supply modules 36. The rear panel 18 can include one or more cooling air outlets 38 through which cooling air within the interior space 24 can exit the appliance 10, and a network interface module with a plurality of network ports 40 and other connectors that are accessible via the rear panel 18.

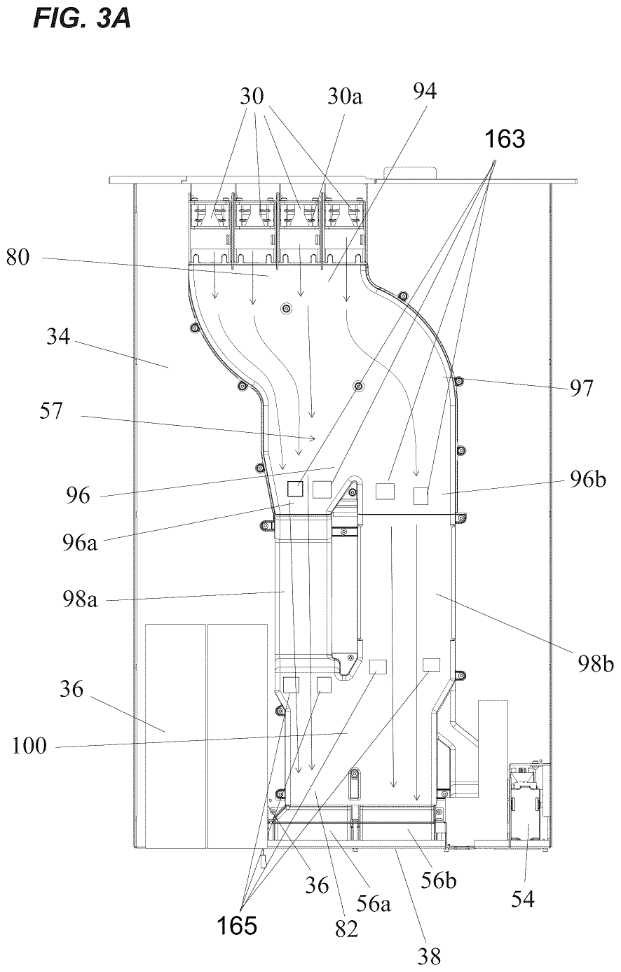

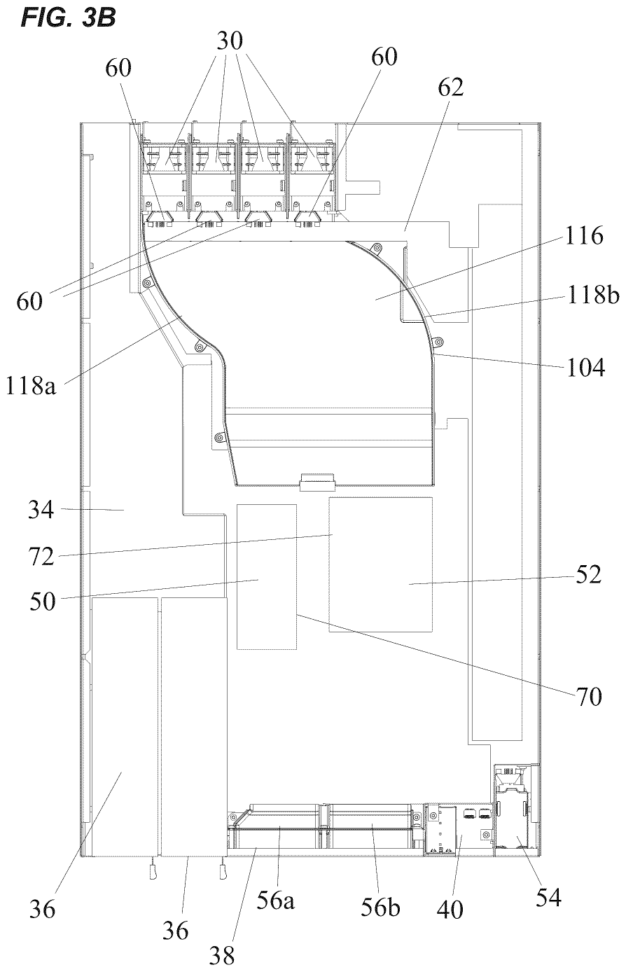

Referring to FIGS. 2, 3A and 3B, a number of components are disposed within the interior space 24 including the fans 30, the power supply modules 36, the network interface module/network ports 40, one or more HSM(s) 50, a processor module 52, and one or more battery modules 54. The HSM(s) 50 is generally of standard construction and operation including having at least one cryptographic key stored thereon. The processor module 52 is also generally of standard construction and operation and is in communication with the HSM(s) 50 and controls operation of the HSM(s) 50 and the appliance 10 as a whole. In addition, the appliance 10 is depicted as including first and second baffle assemblies 56a, 56b in the air outlets 38. The baffle assemblies 56a, 56b include baffles therein that are positioned and shaped to help prevent a probe from being inserted through the baffle assemblies 56a, 56b and reaching the HSM(s) 50 and the processor module 52 to enhance security. The baffles in the baffle assemblies 56a, 56b can have any shape suitable to prevent probe insertion. In an embodiment, the baffles in the baffle assemblies 56a, 56b may have a shape that is similar to the shape of the baffles in the cooling air ducting described below.

The cooling fans 30 are part of a cooling system within the interior space 24 for cooling the HSM(s) 50 and the processor module 52, and optionally the network interface module. The cooling fans 30 are adjacent the front panel 16 which may be considered a first end wall of the housing 12. The cooling fans 30 draw cooling air into the interior space 24 through the fan panel section 28. The cooling system further includes cooling air ducting 57 that extends from the cooling fans 30 to the cooling air outlet(s) 38. As described in further detail below, the cooling air ducting 57 covers the HSM(s) 50 and the processor module 52 and directs cooling air that is drawn into the interior space via the fans 30 over the HSM(s) 50 and the processor module 52 before the cooling air flows to the cooling air outlet(s) 38.

Referring to FIGS. 2 and 3B, each cooling fan 30 is hot swappable. As used herein, hot swappable means that each individual cooling fan 30 can be removed and replaced without stopping, shutting down, or rebooting the appliance 10. When a cooling fan 30 is swapped out, the remaining cooling fans (and the fan controller) have sufficient capacity to compensate for the missing cooling fan. The rear end of each cooling fan 30 includes a connector that is releasably connected to a respective connector 60 on a fan interface board 62. In the illustrated embodiment, there is one connector 60 for each fan 30.

The battery module(s) 54 provide power to maintain some functions of the HSM appliance 10 and the HSM(s) 50 when main power has been removed. The battery module(s) 54 may be hot swappable whereby the battery module(s) 54 can be replaced without stopping or shutting down the HSM appliance 10.

The power supply module(s) 36 may be hot swappable whereby the power supply module(s) 36 can be replaced without stopping or shutting down the HSM appliance 10.

As best seen in FIG. 3B, the HSM(s) 50 and the processor module 52 are positioned relative to one another within the interior space 24 whereby the HSM(s) 50 and the processor module 52 overlap one another. In particular, a side edge 70 of the HSM(s) 50 and a side edge 72 of the processor module 52 overlap one another and face one another. In an embodiment, the side edges 70, 72 may overlap one another by 25% or more. In another embodiment, the side edges 70, 72 may overlap one another by 50% or more. In another embodiment, the side edges 70, 72 may overlap one another by 75% or more. In another embodiment, the side edges 70, 72 may overlap one another by 90% or more. The HSM(s) 50 and the processor module 52 are located close to one another in a side-by-side arrangement to facilitate the distribution of cooling air from the cooling fans 30 to the HSM(s) 50 and the processor module 52 for more efficient use of the cooling air and more efficient cooling of the HSM(s) 50 and the processor module 52. In an embodiment, the side edges 70, 72 may be parallel to one another.

Referring to FIGS. 3A and 3B along with FIG. 2, the cooling air ducting 57 covers the HSM(s) 50 and the processor module 52 and directs cooling air that is drawn into the interior space 24 via the fans 30 over the HSM(s) 50 and the processor module 52 before the cooling air flows to the cooling air outlet(s) 38. FIG. 3A depicts the cooling air ducting 57 in place and extending from a first end 80 at the cooling fans 30 to a second end 82 at the cooling air outlet(s) 38. FIG. 3B depicts a top wall of the ducting 57 removed from the ducting extending from the fans 30 to the outlet(s) 38 to show the position of the HSM(s) 50 and the processor module 52 relative to the ducting 57.

The ducting 57 may be formed in any manner to direct the cooling air from the fans 30 over the HSM(s) 50 and the processor module 52 and then to the outlet(s) 38. In an embodiment, the ducting 57 is configured whereby the cooling air flowing through the ducting 57 is turned less than 90 degrees within the ducting 57. In other words, the cooling air does not have to turn a right angle or more anywhere in the ducting 57. This facilitates the flow of the cooling air through the ducting 57.

With reference to FIGS. 2, 3A, 3B and 4A-C, the cooling air ducting 57 includes a first section 90 (which may also be referred to as an upstream section since it is upstream of the HSM(s) 50 and the processor module 52) and a second section 92 (which may also be referred to as a downstream section since it is downstream of the first section 90). The first section 90 and the second section 92 are depicted as being separately formed from one another but detachably connected to one another to form the ducting 57 and allowing the sections 90, 92 to be separately installed and removed. However, the first section 90 and the second section 92 may be integrally formed with one another as a unitary, one-piece construction to form a unitary, one-piece cooling air ducting 57.

Referring to FIG. 3A, the first section 90 includes an inlet portion 94 at the first end 80 that forms a duct inlet and a cooling air inlet plenum. The duct inlet may be parallel to a direction of the cooling air that is output from the cooling fans 30. As a result, the cooling air output from the cooling fans 30 enters the first section 90 of the ducting 57 without changing direction of the cooling air. The first section 90 further includes an outlet portion 96 at which the ducting is split into a first ducting branch 96a and a second ducting branch 96b. A first portion of the cooling air flows through the first ducting branch 96a and over the HSM(s) 50, while a second portion of the cooling air flows through the second ducting branch 96b and over the processor module 52. The flow paths defined by the first ducting branch 96a and the second ducting branch 96b are parallel to the cooling air output from the cooling fans 30. Between the inlet portion 94 and the ducting branches 96a, 96b, the first section 90 includes a curved section 97 through which the cooling air is gently turned by less than 90 degrees as the cooling air transitions from the inlet portion 94 to the ducting branches 96a, 96b.

With continued reference to FIG. 3A, the second section 92 includes a first ducting branch 98a that corresponds to and mates with the first ducting branch 96a and that includes the HSM(s) 50, and a second ducting branch 98b that corresponds to and mates with the second ducting branch 96b and that includes the processor module 52. The first and second ducting branches 98a, 98b then merge with one another to form an outlet plenum 100. The cooling air from the ducting branch 96a flows into the ducting branch 98a and over the HSM(s) 50 and then into the outlet plenum 100. Similarly, the cooling air from the ducting branch 96b flows into the ducting branch 98b and over the processor module 52 and then into the outlet plenum 100. The flow paths defined by the first ducting branch 98a and the second ducting branch 98b are parallel to the flow paths in the ducting branches 96a, 96b, and parallel to the cooling air output from the cooling fans 30. The flow path of the cooling air in the outlet plenum 100 is parallel to the output direction of the outlet(s) 38 and parallel to the flow paths through the ducting branches 96a, 96b, 98a, 98b.

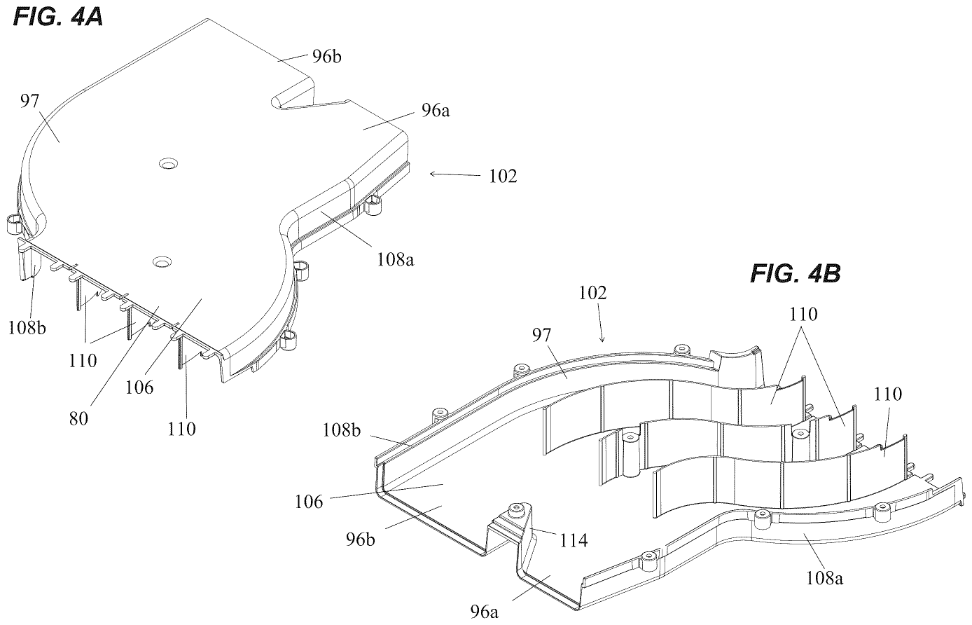

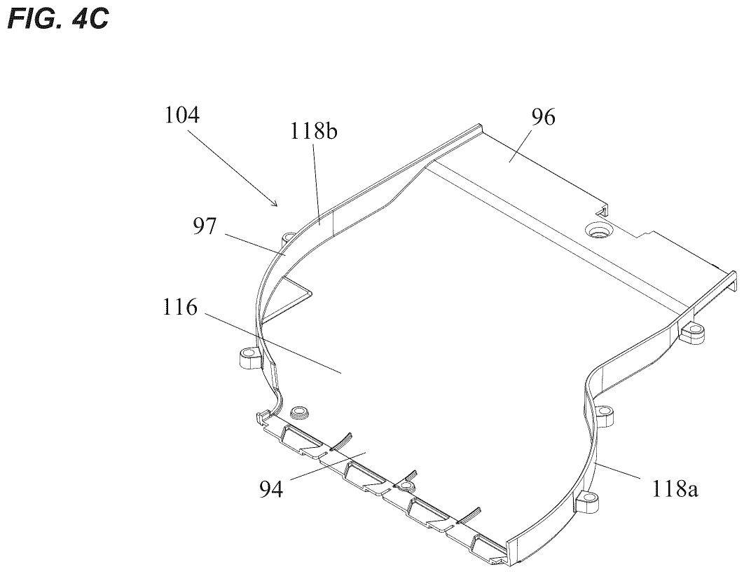

As best seen in FIGS. 2 and 4A-C, when the first section 90 and the second section 92 are separate from one another, the first section 90 may be formed by an upper portion 102 and a lower portion 104. The upper portion 102 and the lower portion 104 mate with one another to form an enclosed air flow duct of the first section 90.

FIGS. 2 and 3B depict the upper portion 102 removed from the lower portion 104. As best seen in FIGS. 4A and 4B, the upper portion 102 includes an upper wall 106 and a pair of side walls 108a, 108b. Guide vanes 110 extend down from the upper wall 106 within the curved section 97 to help guide the cooling air in the curved section 97 as the cooling air transitions between the inlet portion 94 and the outlet portion 96. In an embodiment, the guide vanes 110 may extend from the first end 80, through the curved section 97, and toward the outlet portion 96 stopping short of the ducting branches 96a, 96b. In addition, baffles may extend down from the upper wall 106 between the curved section 97 and the ducting branches 96a, 96b. The baffles, if present, are positioned and shaped to help prevent a probe inserted into the appliance 10 from reaching the HSM(s) 50 and the processor module 52 to enhance security. The baffles can have any shape suitable to prevent probe insertion. The baffles may extend across the entire width of the duct. Further, a splitter 114 extends down from the upper wall 106 to split the cooling air and define the ducting branches 96a, 96b.

Referring to FIGS. 2, 3 and 4C, the lower portion 104 includes a lower wall 116 and a pair of side walls 118a, 118b that extend upwardly therefrom. In addition, baffles may extend upwardly from the lower wall 116 at a location corresponding to any baffles on the upper portion. The baffles, if present, are positioned and shaped to help prevent a probe from reaching the HSM(s) 50 and the processor module 52 to enhance security. The baffles can have any shape suitable to prevent probe insertion. The baffles may extend across the entire width of the duct and are positioned to fit between (i.e. interleave with) the baffles of the upper portion 102.

In operation, the upper portion 102 and the lower portion 104 are brought together, mated, and secured together. The side walls 108a, 108b mate with the side walls 118a, 118b, respectively, and together with the walls 106, 116 form an enclosed duct. The tips of the guide vanes 110 extend close to or in contact with the lower wall 116, and the baffles, if present, are interleaved with one another with tips thereof extending close to or in contact with the lower wall 116 or the upper wall 106.

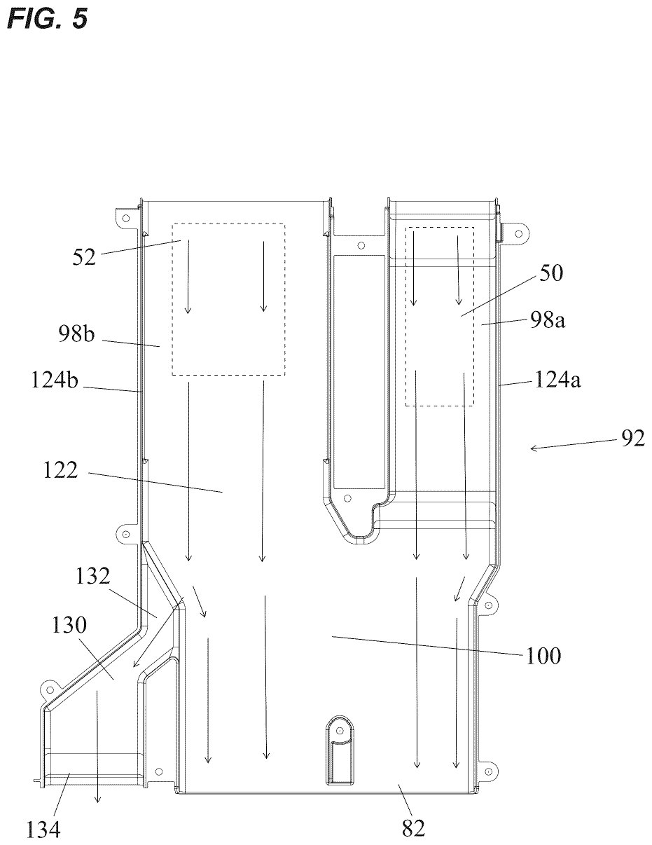

Referring to FIGS. 2 and 5, the second section 92 of the cooling air ducting 57 is depicted. FIG. 3A shows the second section 92 in position, while FIG. 3B depicts the second section 92 as being removed. The second section 92 includes a top wall 122 that is disposed over and covers the tops of the HSM(s) 50 and the processor module 52, and side walls 124a, 124b that extend downward from the top wall 122 to constrain the cooling air as it flows over and past the HSM(s) 50 and the processor module 52 (a representation of the locations of the HSM(s) 50 and the processor module 52 when they are covered by the second section 92 is depicted in broken lines in FIG. 5). The second section 92 also defines the second end 82. The arrows in FIG. 5 depict the flow of the cooling air in the second section 92. The first and second ducting branches 98a, 98b are fluidly separate from one another where they cover the HSM(s) 50 and the processor module 52, and thereafter merge into the outlet plenum 100. In the illustrated example, the second section 92 includes an open bottom that is not closed by a bottom wall. However, in another embodiment, the second section 92 may include a bottom wall that has openings where the HSM(s) 50 and the processor module 52 are located to allow installation of the second section 92 over the HSM(s) 50 and the processor module 52.

In operation, the second section 92 is connected to the first section 90 with the first ducting branch 98a connected to the first ducting branch 96a, and the second ducting branch 98b connected to the second ducting branch 96b. The cooling air from the ducting branch 96a flows into the ducting branch 98a and over the HSM(s) 50 and then into the outlet plenum 100. Similarly, the cooling air from the ducting branch 96b flows into the ducting branch 98b and over the processor module 52 and then into the outlet plenum 100. The cooling air in the outlet plenum 100 flows parallel to the output direction of the outlet(s) 38.

Referring to FIG. 3A, the cooling fans 30 output the cooling air in a first direction as indicated by the arrows. The cooling air then flows into the inlet portion 94 (i.e. duct inlet) of the cooling air ducting 57 which is parallel to the first direction. The cooling air then flows into the curved section 97 with the guide vanes 110 helping to guide the cooling air through the curved section 97. The cooling air ultimately emerges from the guide vanes 110 with the cooling air parallel to the initial air flow from the cooling fans 30 before splitting into the first and second ducting branches 96a, 96b. The cooling air then flows into the first and second ducting branches 98a, 98b to cool the HSM(s) 50 and the processor module 52. The cooling air then merges together in the outlet plenum 100 and then flows into the baffle assemblies 56a, 56b and out of the outlet(s) 38. As best seen in FIGS. 3A and 3B, the ducting 57 may be configured so that the discharge axis of at least one of the cooling fans 30 (such as the fan 30a) extends through the HSM(s) 50. This highlights that the ducting 57 is configured to eliminate sharp turns (i.e. turns that are 90 degrees or more) of the cooling air through the ducting 57 to make the air flow more efficient and more effective at cooling. In addition, because the cooling air flow directly from the cooling fans 30 and into the ducting 57, and the cooling air flow is constrained by the ducting 57 as the cooling air flows to and past the HSM(s) 50 and the processor module 52, more effective cooling is achieved since the cooling air is at a lower temperature compared to if the cooling air is mixed with bulk air within the interior space 24 prior to reaching the HSM(s) 50 and the processor module 52.

Referring to FIGS. 2, 3A and 5, the ducting 57 can optionally include a branch channel 130 that directs cooling air onto the network ports 40 of the network interface module. If present, the branch channel 130 may extend anywhere from the ducting 57. For example, in the illustrated example, the branch channel 130 is depicted as extending from the ducting 57 downstream from the processor module 52, for example where the ducting branch 98b and the ducting branch 98a begin to merge into the outlet plenum 100. If present, the branch channel 130 includes a cooling air inlet 132 in communication with the cooling air flowing through the ducting 57 and a cooling air outlet 134 that in use is positioned to discharge onto the network ports 40. If present, the branch channel 130 can include baffles extending across the width thereof that are positioned and shaped to help prevent a probe from being inserted and reaching the HSM(s) 50 and the processor module 52 to enhance security. The baffles can have any shape that is suitable to prevent probe insertion.

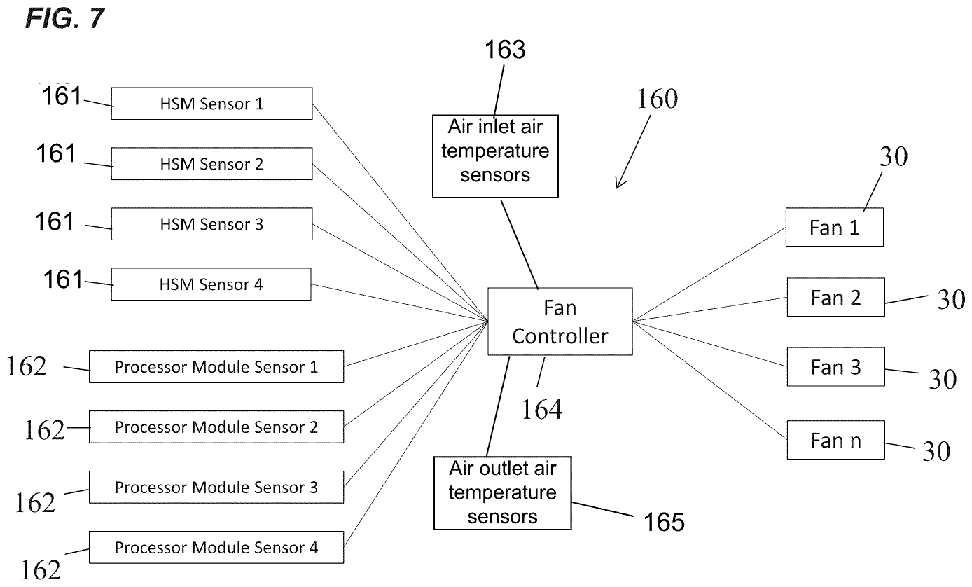

Referring to FIG. 7 together with FIGS. 3A-B, an example of a real-time dynamic fan speed control system 160 is depicted. In FIG. 7, elements that are the same as or similar to elements in FIGS. 1-5 are referenced using the same reference numerals. The system 160 is configured to dynamically control, in real-time, the speed of one or more of the cooling fans 30 based on one or more factors including, but not limited to, the real-time temperature of one or more of the HSM(s) 50 and/or of the processor module 52, and/or based on the real-time temperature of the airflow through the ducting 57. For example, in one example, one or more temperature sensors 161 (shown in FIG. 7) may be provided on each one of the HSM(s) 50 to sense the temperature of each HSM(s) 50, and one or more temperature sensors 162 (shown in FIG. 7) may be provided on the processor module 52 to sense the temperature of the processor module 52. FIG. 7 illustrates four of the temperature sensors 161 associated with each HSM 50 and four of the temperature sensors 162 associated with the processor module 52. However, a single temperature sensor 161, 162, two of the temperature sensors 161, 162, three of the temperature sensors 161, 162 or more than four of the temperature sensors 161, 162 can be provided. In another example, one or more air temperature sensors 163 (shown in FIGS. 3A and 7) may be provided before the HSM(s) 50 and/or before the processor module 52 and one or more air temperature sensors 165 (shown in FIGS. 3A and 7) may be provided after the HSM(s) 50 and/or after the processor module 52. The temperature sensors 163, 165 are configured to detect the local air temperature of the cooling air in the ducting with the difference in air temperature of the sensors 163, 165 being a measure of an increase in temperature (if any) of the cooling air as a result of flowing past the HSM(s) 50 and/or the processor module 52. Based on the temperature measurement(s) of the sensors 161, 162, and/or based on the measurements of the sensors 163, 165, the speed of one or more of the cooling fans 30 may be adjusted up or down depending upon the cooling needs of the HSM(s) 50 and/or the processor module 52.

FIG. 3A depicts two of the air temperature sensors 163, 165 positioned upstream and downstream of the HSM(s) 50, and two of the air temperature sensors 163, 165 positioned upstream and downstream of the processor module 52. However, a smaller or larger number of the temperature sensors 163, 165 can be used. In addition, the temperature sensors 163, 165, or additional temperature sensors, may be located at different locations in the ducting 57 to detect air flow temperatures at different locations of the ducting 57 than depicted in FIG. 3A. For example, there can be one or more air temperature sensors in the ducting 57 adjacent to the outlets of the cooling fans 30, there can be one or more air temperature sensors in the ducting 57 adjacent to the cooling air outlets 38, and there can be one or more air temperature sensors in each branch of the cooling air ducting 57 including the branch channel 130. The locations of the air temperature sensors 163, 165 depicted in FIG. 3A are examples only.

As shown in FIG. 7, the temperature readings from the temperature sensors 161, 162, 163, 165 may be directed to a fan controller 164 which analyses the temperature readings to determine if an adjustment of the speed of one or more of the fans 30 is deemed appropriate. The fan controller 164 may be part of an appliance controller of the appliance 10 that is separate from the processor module 52 or may be a controller that is separate from the appliance controller and separate from the processor module 52.

For example, with respect to the HSM(s) 50, the sensors 161 may determine that the temperature of the HSM(s) 50 exceeds a predetermined threshold, and/or a large temperature increase (for example that exceeds a predetermined threshold, stored for example in the fan controller 164) of the airflow over the HSM(s) 50 indicates that the HSM(s) 50 may be producing greater than expected heat which may indicate that the speed of one or more of the fans 30 should be increased to provide additional cooling air to the HSM(s) 50. A temperature of the HSM 50 detected by the sensors 161 that is within the predetermined threshold and/or an air temperature increase within the predetermined threshold may indicate that the HSM(s) 50 is producing expected heat which may indicate that the speed of the fans 30 can remain unchanged to provide the same level of cooling air to the HSM(s) 50. A temperature of the HSM 50 detected by the sensors 161 that is below the predetermined threshold and/or a temperature increase below the predetermined threshold may indicate that the HSM(s) 50 is producing less expected heat which may indicate that the speed of one or more of the fans 30 can be reduced to reduce the level cooling air to the HSM(s) 50. As an example only, in the example of a temperature difference determined by the sensors 163, 165, the predetermined threshold (which may be referred to as an HSM predetermined threshold) could be a temperature of 1-3 degrees C., and any temperature difference greater than 3 degrees C. could result in an increase in fan speed, a temperature difference within the 1-3 degrees threshold could result in the fan speed remaining unchanged, and a temperature difference that is less than 1 degrees C. could result in a reduction of fan speed.

Similarly, with respect to the processor module 52, the sensors 162 may determine that the temperature of the processor module 52 exceeds a predetermined threshold, and/or a large temperature increase (for example that exceeds a predetermined threshold, stored for example in the fan controller 164) of the airflow over the processor module 52 indicates that the processor module 52 may be producing greater than expected heat which may indicate that the speed of one or more of the fans 30 should be increased to provide additional cooling air to the processor module 52. The predetermined threshold (which may be referred to as the processor module threshold) may be the same as or different than the predetermined threshold for the HSM(s) 50. A temperature of the processor module 52 detected by the sensors 162 that is within the predetermined threshold and/or an air temperature increase within the predetermined threshold may indicate that the processor module 52 is producing expected heat which may indicate that the speed of the fans 30 can remain unchanged to provide the same level of cooling air to the processor module 52. A temperature of the processor module 52 detected by the sensors 162 that is below the predetermined threshold and/or a temperature increase below the predetermined threshold may indicate that the processor module 52 is producing less expected heat which may indicate that the speed of one or more of the fans 30 can be reduced to reduce the level cooling air to the processor module 52. As an example only, in the example of a temperature difference determined by the sensors 163, 165, the predetermined threshold for the processor module 52 could be a temperature of 3-5 degrees C. (or 1-3 degrees C. like with the HSM(s) 50), and any temperature difference greater than 5 degrees C. could result in an increase in fan speed, a temperature difference within 3-5 degrees threshold could result in the fan speed remaining unchanged, and a temperature difference that is less than 3 degrees C. could result in a reduction of fan speed.

In an embodiment, rather than measuring a temperature difference across the HSM(s) 50 and/or the processor module 52, one or more temperature sensors 162 can be provided to measure airflow temperature at a single location (or multiple locations) upstream or downstream of the HSM(s) 50 and/or the processor module 52 and based on the airflow temperature at that location(s) adjust the fan speed up or down (or remain unchanged). Over time, one may know, based on gleaned knowledge of appliance usage and HSM(s) 50 and processor module 52 temperature patterns, the airflow temperature level that provides the desired cooling of the HSM(s) 50 and/or the processor module 52 based on factors such as, but not limited to, the time of day; the usage of the appliance 10, the HSM(s) 50 and the processor module 52; the ambient temperature where the appliance 10 is located; and other factors. These single airflow temperature readings may be sufficient to determine real-time cooling needs and thereby control the speed of one or more of the fans 30. In another embodiment, the fan controller 164 may receive fan speed readings from each cooling fan, for example the revolutions per minute of each fan, which may be used by the fan controller 164 in controlling the speed of the fans.

Alternatively, the fan controller 164 may be programmed to automatically control the speed of one or more of the fans 30 using gleaned knowledge of appliance usage and HSM(s) 50 and processor module 52 temperature patterns based on factors such as, but not limited to, the time of day; the usage of the appliance 10, the HSM(s) 50 and the processor module 52; the ambient temperature where the appliance 10 is located; and other factors. This automatic control may occur without using any temperature sensors, or with the temperature sensors 162 present.

The fan controller 164 may also be programmed in a manner to one or more of: a) understand the ‘state’ of the HSM appliance 10 which may be used to, for example, better control the appliance; b) generate detailed reports and possibly provide the reports to a remote monitoring system which may be used to, for example, enable remote debugging and proactive monitoring of the appliance 10 thereby giving users more information on appliance operation including, but not limited to, cooling fan failures and/or overheating of components and also help users better understand the environment that the appliance 10 is located in, such as a data center.

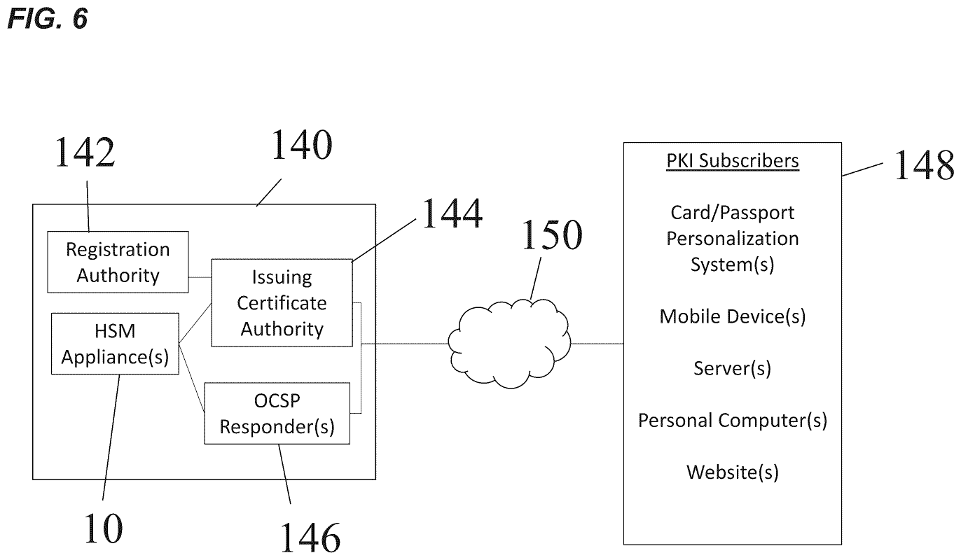

FIG. 6 depicts an example application of the HSM appliance 10. In this example, the HSM appliance 10 is depicted as providing cryptographic security services in a PKI deployment to the back-end of a high-volume cloud deployment. High-volume refers to a high transaction rate of a PKI application. Cloud deployment means that the various services 142, 144, 146 described below may be located in hardware that may be distributed at any location around the globe, with more hardware allocated to the services as demand requires, and optionally some degree of resource sharing. For example, the appliance 10 may be part of an online issuing certificate authority (CA) enclave 140 that can include at least one registration authority 142, at least one issuing CA 144, and at least one Online Certificate Status Protocol (OCSP) responder 146. A number of PKI subscribers 148 may be in communication with the CA enclave 140 via a suitable network 150 such as the cloud, the internet, a wide area network, a local area network, or other network.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A hardware security module appliance comprising:
a housing defining an interior space;
a hardware security module disposed in the interior space, the hardware security module having at least one cryptographic key stored thereon;
a processor module disposed in the interior space, the processor module is in communication with the hardware security module and controls operation of the hardware security module;
the hardware security module and the processor module are positioned relative to one another within the interior space whereby the hardware security module and the processor module overlap one another.

2. The hardware security module appliance of claim 1, wherein the hardware security module includes a side edge and the processor module includes a side edge, and the side edge of the hardware security module overlaps the side edge of the processor module.

3. The hardware security module appliance of claim 2, wherein the side edge of the hardware security module is parallel to the side edge of the processor module.

4. The hardware security module appliance of claim 1, further comprising cooling fans within the interior space that draw cooling air into the interior space, and the cooling fans are hot swappable.

5. The hardware security module appliance of claim 1, further comprising a cooling system within the interior space; the cooling system includes cooling fans adjacent a first end panel of the housing that draw cooling air into the interior space, cooling air outlets in a second end panel of the housing opposite the first end panel through which cooling air drawn into the interior space exits the interior space, cooling air ducting that extends from the cooling fans to the cooling air outlets, and the cooling air ducting covers the hardware security module and the processor module and directs cooling air that is drawn into the interior space over the hardware security module and the processor module before the cooling air flows to the cooling air outlets.

6. The hardware security module appliance of claim 5, further comprising at least one of the following:
the cooling air ducting is configured whereby the cooling air flowing through the cooling air ducting is turned less than 90 degrees within the cooling air ducting;
the cooling fans output the cooling air in a first direction; and the cooling air ducting includes a duct inlet that is parallel to the first direction;
the cooling air ducting includes a cooling air inlet plenum, a first ducting branch that extends from the cooling air inlet plenum and that covers the hardware security module, and a second ducting branch that extends from the cooling air inlet plenum and that covers the processor module, and the second ducting branch is fluidly separate from the first ducting branch.

7. The hardware security module appliance of claim 6, wherein the first ducting branch and the second ducting branch fluidly connect with one another downstream of the hardware security module and the processor module to form a cooling air outlet plenum that is fluidly connected to the cooling air outlets.

8. The hardware security module appliance of claim 1, further comprising at least two power supply modules within the interior space, and a battery module within the interior space.

9. The hardware security module appliance of claim 5, further comprising cooling air ducting that directs cooling air to a network interface module that includes a plurality of network ports.

10. A system comprising:
the hardware security module appliance of claim 1.

11. A hardware security module appliance comprising:
a housing defining an interior space;
a hardware security module disposed in the interior space, the hardware security module having at least one cryptographic key stored thereon;
a processor module disposed in the interior space, the processor module is in communication with the hardware security module and controls operation of the hardware security module;
a cooling system within the interior space; the cooling system includes cooling fans adjacent a first end panel of the housing that draw cooling air into the interior space, cooling air outlets in a second end panel of the housing opposite the first end panel through which cooling air drawn into the interior space exits the interior space, cooling air ducting that extends from the cooling fans to the cooling air outlets, and the cooling air ducting covers the hardware security module and the processor module and directs cooling air that is drawn into the interior space over the hardware security module and the processor module before the cooling air flows to the cooling air outlets.

12. The hardware security module appliance of claim 11, wherein the cooling fans are hot swappable.

13. The hardware security module appliance of claim 11, further comprising at least one of the following:
the cooling air ducting is configured whereby the cooling air flowing through the cooling air ducting is turned less than 90 degrees within the cooling air ducting;
the cooling fans output the cooling air in a first direction; and the cooling air ducting includes a duct inlet that is parallel to the first direction;
the cooling air ducting includes a cooling air inlet plenum, a first ducting branch that extends from the cooling air inlet plenum and that covers the hardware security module, and a second ducting branch that extends from the cooling air inlet plenum and that covers the processor module, and the second ducting branch is fluidly separate from the first ducting branch.

14. The hardware security module appliance of claim 13, wherein the first ducting branch and the second ducting branch fluidly connect with one another downstream of the hardware security module and the processor module to form a cooling air outlet plenum that is fluidly connected to the cooling air outlets.

15. The hardware security module appliance of claim 11, further comprising cooling air ducting that directs cooling air to a network interface module that includes a plurality of network ports.

16. The hardware security module appliance of claim 11, further comprising at least two power supply modules within the interior space, and a battery module within the interior space.

17. A system comprising:
the hardware security module appliance of claim 11.

18. A hardware security module appliance comprising:
a housing defining an interior space;
a hardware security module disposed in the interior space, the hardware security module having a plurality of cryptographic keys stored thereon;
a processor module disposed in the interior space, the processor module is in communication with the hardware security module and controls operation of the hardware security module;
a cooling system within the interior space; the cooling system includes cooling fans adjacent a first end panel of the housing that draw cooling air into the interior space, cooling air outlets in a second end panel of the housing opposite the first end panel through which cooling air drawn into the interior space exits the interior space, and cooling air ducting that distributes cooling air from the cooling fans within the interior space; and
at least two of the following:
a) the hardware security module and the processor module are positioned relative to one another within the interior space so that sides of the hardware security module and the processor module overlap one another;
b) the cooling air ducting extends from the cooling fans to the cooling air outlets, and the cooling air ducting covers the hardware security module and the processor module and directs cooling air that is drawn into the interior space over the hardware security module and the processor module before the cooling air flows to the cooling air outlets;
c) the cooling air ducting is configured whereby the cooling air flowing through the cooling air ducting is turned less than 90 degrees; and
d) each cooling fan has a discharge axis, and the discharge axis of at least one of the cooling fans extends through the hardware security module.

19. The hardware security module appliance of claim 18, comprising three or more of a), b), c) and d).

20. The hardware security module appliance of claim 18, comprising a), b), c) and d).
